(19) United States
(12) Patent Application Publication
(10) Pub. No.: US 2008/0070382 A1
(43) Pub. Date: Mar. 20, 2008

(54) FIXING APPARATUS FOR SEMICONDUCTOR WAFER

(75) Inventors: Dae-Sang CHAN, Chungcheongnam-do (KR); Jun-Young KO, Chungcheongnam-do (KR); Wha-Su SIN, Chungcheongnam-do (KR)

Correspondence Address: MARGER JOHNSON & MCCOLLOM, P.C., 210 SW MORRISON STREET, SUITE 400, PORTLAND, OR, 97204, US

(73) Assignee: SAMSUNG ELECTRONICS CO., LTD., Gyeonggi-do (KR)

(21) Appl. No.: 11/858,821

(22) Filed: Sep. 20, 2007

(30) Foreign Application Priority Data
Sep. 20, 2006 (KR) 2006-0091381

(51) Int. Cl. H01L 21/78; B28D 7/04

(52) U.S. Cl. 438/464; 125/35; 257/E21.599

(57) ABSTRACT

A wafer fixing apparatus is disclosed including a dicing stage structured to fix a semiconductor wafer. A die attach film is disposed on the dicing stage to attach the semiconductor wafer to the dicing stage. The die attach film attaches the semiconductor wafer to the dicing stage due to the tackiness of the die attach film. A wafer ring, which may be of a metallic material, is coupled to the dicing stage using a wafer ring attaching member.

### CROSS-REFERENCE TO RELATED APPLICATIONS

This U.S. non-provisional patent application claims priority under 35 U.S.C. §119 of Korean Patent Application No. 10-2006-91381 filed on Sep. 20, 2006, the entire contents of which are hereby incorporated by reference.

### BACKGROUND

The present invention relates to apparatuses for manufacturing semiconductor devices and, more particularly, to a fixing apparatus for a semiconductor wafer.

A semiconductor chip package manufacturing process may include multiple steps, such as: a sawing process in which a semiconductor wafer may be sawed into desired-sized dies (or semiconductor chips); a die attaching process in which individual dies are attached to the die pad of a lead frame; a wire bonding process in which the dies and the lead frame are electrically coupled to each other using conductive wire; and a molding process in which the dies are scaled with sealing resin to protect the dies from the external environment.

In the sawing process, the semiconductor wafer may be subjected to electric die sorting (EDS). An adhesive tape may be attached to a lower surface of the semiconductor wafer to prevent the separation of individual dies from the semiconductor wafer. The adhesive tape may include an ultraviolet-curing material (hereinafter referred to as “UV-TAPE”). In order to cut a UV-TAPE-attached semiconductor wafer into individual dies, the wafer may be sawed along scribed lines formed therein.

FIG. 1A shows a top plan view including a conventional wafer fixing apparatus. FIG. 1B shows a cross-sectional view taken along the line I-I′ of FIG. 1A. FIG. 1C shows a partially enlarged cross-sectional view of a portion “A” shown in FIG. 1B.

Referring to FIGS. 1A through 1C, a wafer fixing apparatus may include a dicing stage 20, which may function as a base plate during a process of sawing the semiconductor wafer (not shown) into the individual dies 10a. An adhesive layer hardened by UV-ray (UV-hardened layer) 40 may be disposed over the dicing stage 20 to releasably secure individual dies 10a to the dicing stage 20. A die attach film (DAF) 30 may be disposed between the dicing stage 20 and the semiconductor wafer to couple the individual dies 10a to the dicing stage 20. A wafer ring 50 may be attached to the dicing stage 20 through the medium of the UV-hardened layer 40 interposed therebetween. A film-type dicing stage may be used as the dicing stage 20. The wafer ring 50 may be used to transfer the dicing stage 20, which fixes the semiconductor wafer and the individual dies 10a through the medium of the die attach film 30.

As previously stated, the wafer fixing apparatus may include the UV-hardened layer 40. The UV-hardened layer 40 may be disposed at the edge of the individual dies 10a separated through a semiconductor wafer sawing process. A portion of the UV-hardened layer 40a may be denatured by a blade or laser with respect to sawing the semiconductor wafer. The denatured portion 40a of the UV-hardened layer 40 is not hardened during a UV-irradiation process, which is a preliminary process performed to detach the separated individual dies 10a. As a result, the denatured portion 40a may serve to lock the dicing stage 20 with the individual dies 10a during the wafer sawing process. For this reason, during a process performed to detach the individual dies 10a locked with the dicing stage 20, an increased force must be applied to detach the individual dies 10a, which causes damage to the individual dies 10a and a decrease in process yield. Accordingly, a need remains for an improved fixing apparatus for a semiconductor wafer.

### SUMMARY OF THE INVENTION

Exemplary embodiments of the present invention are directed to a wafer fixing apparatus. In an exemplary embodiment, the wafer fixing apparatus may include: a dicing stage structured to fix a semiconductor wafer; and a die attach film disposed on the dicing stage to couple the semiconductor wafer to the dicing stage, the die attach film adhering to the dicing stage using a tackiness of the die attach film with respect to the dicing stage.

### BRIEF DESCRIPTION OF THE DRAWINGS

FIG. 1A shows a top plan view including a conventional wafer fixing apparatus.

FIG. 1B shows a cross-sectional view taken along a line I-I′ of FIG. 1A.

FIG. 1C shows a partially enlarged cross-sectional view of a portion “A” shown in FIG. 1B.

FIG. 2A shows a top plan view including a wafer fixing apparatus according to an embodiment of the present invention.

FIG. 2B shows a cross-sectional view taken along a line II-II′ of FIG. 2A.

FIG. 3A shows a top plan view including a wafer fixing apparatus according to another embodiment of the present invention.

FIG. 3B shows a cross-sectional view taken along a line III-III′ of FIG. 3A.

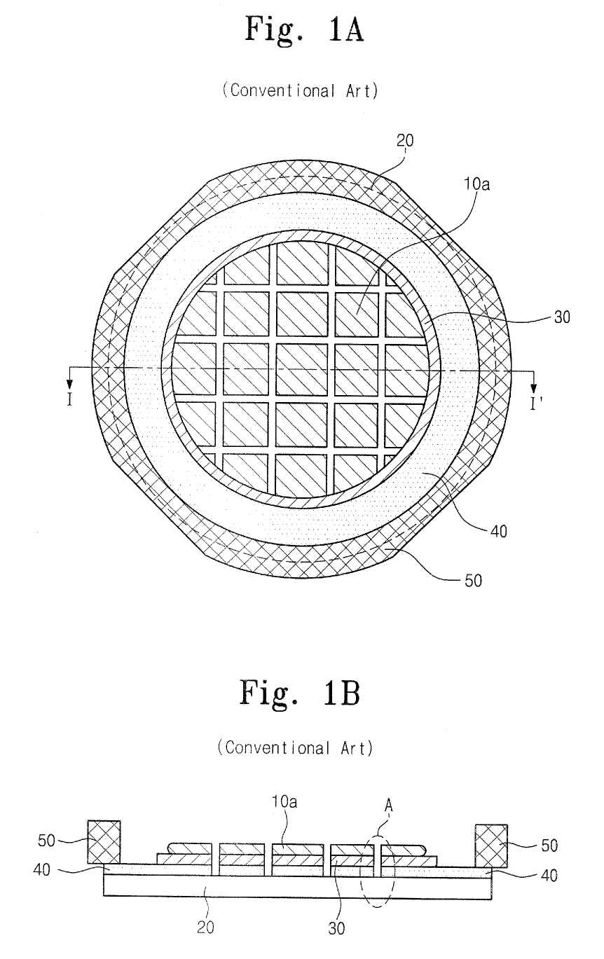

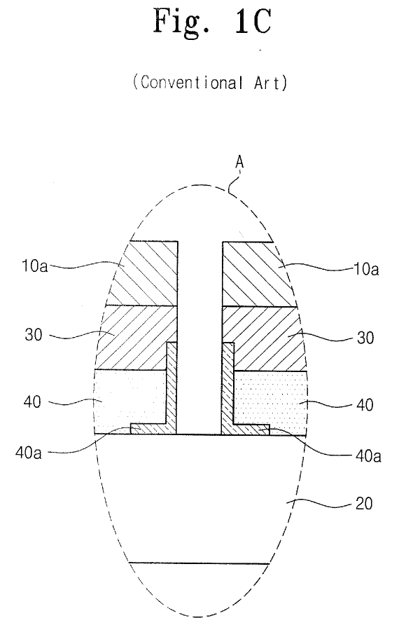

### DETAILED DESCRIPTION OF PREFERRED EMBODIMENTS

The present invention will now be described more fully hereinafter with reference to the accompanying drawings, in which preferred embodiments of the invention are shown. This invention, however, may be embodied in many different forms and should not be construed as limited to the embodiments set forth herein. Rather, these embodiments are provided so that this disclosure will be thorough and complete, and will fully convey the scope of the invention to those skilled in the art. In the drawings, the thicknesses of layers and regions are exaggerated for clarity. It will also be understood that when a layer is referred to as being “on” or “over” another layer or substrate, it can be directly on the other layer or substrate, or intervening layers may also be present. Like numbers refer to like elements throughout.

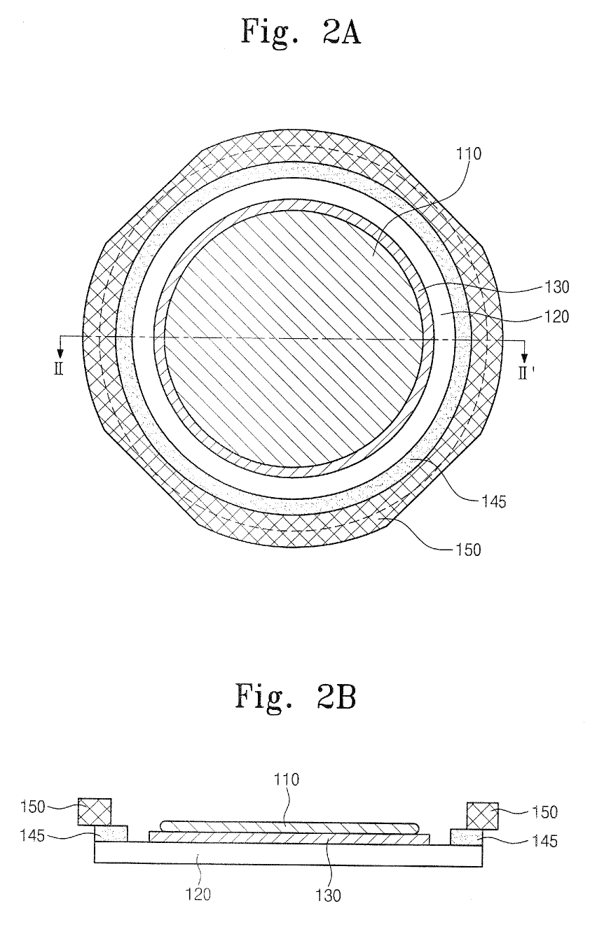

FIG. 2A shows a top plan view including a wafer fixing apparatus according to an embodiment of the present invention. FIG. 2B shows a cross-sectional view taken along a line II-II′ of FIG. 2A.

Referring to FIGS. 2A and 2B, a wafer fixing apparatus may include a dicing stage 120 structured to fix a semiconductor wafer 110. A die attach film 130 may be disposed on the dicing stage 120 to attach the semiconductor wafer 110 to the dicing stage 120. A wafer ring 150 may be attached to the dicing stage 120 through the medium of a wafer ring attaching member 145 may be substantially ring-shaped and interposed therebetween. A film-type dicing stage may be used as the dicing stage 120. The wafer ring 150 coupled to the dicing stage 120 (through the medium of the wafer ring attaching member 145) may be used to transfer the dicing stage 120 including the semiconductor wafer 110 and dies separated through a semiconductor wafer sawing process.

In this embodiment, the dicing stage 120 and the die attach film 130 can be made of a polyolefin group material and an acryl polymer group material, respectively. Thus, the die attach film 130 may be sufficiently attached to the dicing stage 120 due at least partially to the tackiness of the die attach film 130. The wafer ring 150 may be made of a metallic material. The wafer ring attaching member 145 may include an adhesive-coated tape. The wafer ring 150 may overlap a portion of the dicing stage 120, as shown in FIG. 2B, to facilitate a transfer of the dicing stage 120. In other words, the wafer ring 150 may have an inner diameter which is less than the diameter of the dicing stage 120, and an outer diameter which is greater than the diameter of the dicing stage 120. Additionally, the wafer ring 150 may overlap and be attached to the dicing stage 120 through the medium of the wafer ring attach member 145, which may be directly attached to a surface of the dicing stage 120 that includes the die attach film 130 (i.e., an upper surface of the dicing stage 120).

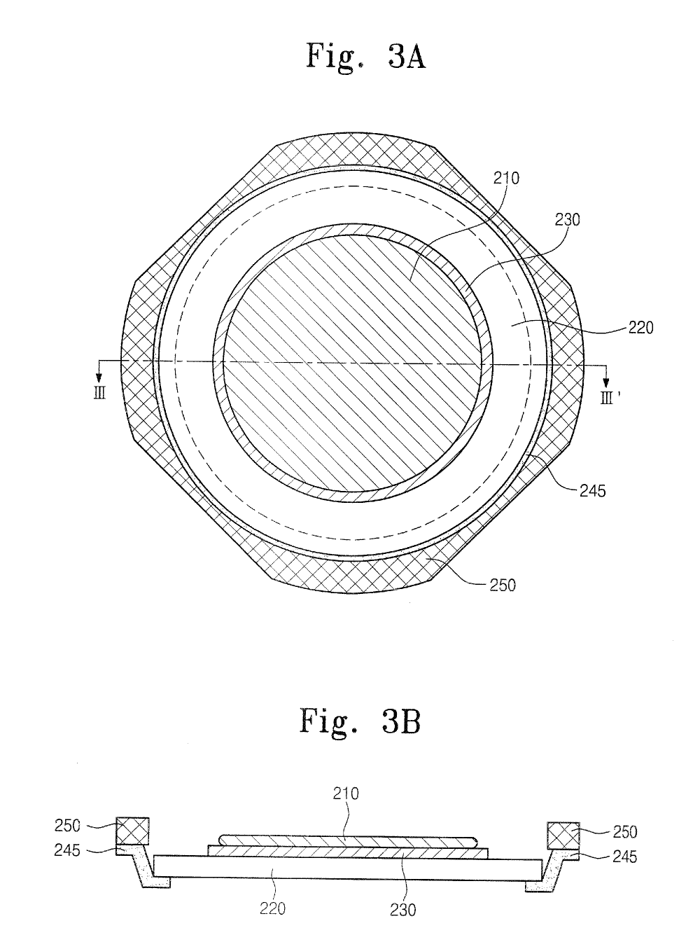

FIG. 3A shows a top plan view including a wafer fixing apparatus according to another embodiment of the present invention. FIG. 3B shows a cross-sectional view taken along a line III-III′ of FIG. 3A.

Referring to FIGS. 3A and 3B, a wafer fixing apparatus may include a dicing stage 220 structured to fix a semiconductor wafer 210. A die attach film 230 may be disposed on the dicing stage 220 to attach the semiconductor wafer 210 to the dicing stage 220. A wafer ring 250 may be attached to the dicing stage 220 through the medium of a wafer ring attaching member 245, which may be substantially ring-shaped. A film-type dicing stage may be used as the dicing stage 220. The wafer ring 250 coupled to the dicing stage 220 (through the medium of the wafer ring attaching member 245) may be used to transfer the dicing stage 220 including the semiconductor wafer 210 and dies separated through a semiconductor wafer sawing process.

In this embodiment, the dicing stage 220 and the die attach film 230 can be made of a polyolefin group material and an acryl polymer group material, respectively. Thus, the die attach film 230 may be sufficiently attached to the dicing stage 220 due at least partially to the tackiness of the die attach film 230. The wafer ring 250 may be made of a metallic material. The wafer ring attaching member 245 may include an adhesive-coated tape. The wafer ring 250 may be spaced apart from the edge of the dicing stage 220, as shown in FIG. 3B. In other words, the wafer ring 250 may have an inner diameter and an outer diameter which are both greater than the diameter of the dicing stage 220. Additionally, the wafer ring 250 may be spaced apart from and indirectly attached to the dicing stage 220 through the medium of the wafer ring attaching member 245, which may be directly attached to a surface of the dicing stage 220 that does not include the die attach film 230 (i.e., a lower surface of the dicing stage 220). The spacing of the wafer ring 250 apart from the dicing stage 220 enhances stability and improves transfer reliability of the dicing stage 220.

According to some embodiments, an adhesive material hardened by UV-ray is no longer required. Therefore, a problem is overcome with respect to the conventional apparatus where dies formed through a semiconductor wafer sawing process are locked with the dicing stage, and potentially damaged. In some embodiments of the present invention, because the wafer fixing apparatuses do not include an adhesive material hardened by UV-ray, a die attach film may be used to adhere the semiconductor wafer and dies to the dicing stage due at least partially to the tackiness of the die attach film. The adhesion associated with the tackiness of the die attach film is lower in strength than a typical adhesion. Accordingly, a laser is preferably used to cut the semiconductor wafer into individual dies, which keeps pace with the recent trend toward the use of semiconductor wafers having a thickness of 100 micrometers or less.

Further, because some embodiments of the present invention do not include an adhesive material hardened by UV-ray, the UV-irradiation process (which is a preliminary process performed to detach the individual dies) may be omitted to simplify a semiconductor wafer sawing process and a die detaching process. As a result, it is possible to prevent the individual dies separated through a semiconductor wafer sawing process from locking with the wafer fixing apparatus. As such, embodiments of the present invention make it easy to detach the separated individual dies during a die detaching process. In other words, a force applied to the separated individual dies may be reduced during the die detaching process; thus, the separate individual dies are protected from damage, which improves overall process yield.

According to some embodiments of the present invention, a wafer fixing apparatus is not required to include an adhesive material hardened by UV-ray. Therefore, it is possible to prevent the individual dies separated through a semiconductor wafer sawing process from locking with the wafer fixing apparatus. For this reason, the individual dies separated by sawing a semiconductor wafer are easily detached.

Although the present invention has been described in connection with the exemplary embodiments of the present invention illustrated in the accompanying drawings, it is not limited thereto. It will be apparent to those skilled in the art that various substitutions, modifications and changes may be made without departing from the scope and spirit of the invention.

What is claimed is:

1. A wafer fixing apparatus comprising:
a dicing stage structured to fix a semiconductor wafer; and
a die attach film disposed on the dicing stage to attach the semiconductor wafer to the dicing stage, the die attach film adhering to the dicing stage using a tackiness of the die attach film with respect to the dicing stage.

2. The wafer fixing apparatus of claim 1, further comprising:
a wafer ring coupled to the dicing stage using a wafer ring attaching member and structured to transfer the dicing stage fixing the semiconductor wafer.

3. The wafer fixing apparatus of claim 1, wherein the dicing stage is made of a polyolefin group material.

4. The wafer fixing apparatus of claim 1, wherein the die attach film is made of an acryl polymer group material.

5. The wafer fixing apparatus of claim 2, wherein the wafer ring is made of a metallic material.

6. The wafer fixing apparatus of claim 2, wherein the wafer ring attaching member is substantially ring-shaped.

7. The wafer fixing apparatus of claim 6, wherein the wafer ring attaching member is an adhesive-coated tape.

8. The wafer fixing apparatus of claim 5, wherein the wafer ring overlaps a portion of the dicing stage.

9. The wafer fixing apparatus of claim 8, wherein the wafer ring overlaps and is coupled to a surface of the dicing stage using the wafer ring attaching member.

10. The wafer fixing apparatus of claim 1, wherein the wafer ring is laterally spaced apart from an edge of the dicing stage.

11. The wafer fixing apparatus of claim 10, wherein the wafer ring is coupled to a surface of the dicing stage that does not include the die attach film, using the wafer ring attaching member.

12. The wafer fixing apparatus of claim 11, wherein the wafer ring has an inner diameter which is greater than a diameter of the dicing stage.

13. The wafer fixing apparatus of claim 6, wherein the wafer ring is coupled to a lower surface of the dicing stage using the substantially ring-shaped attaching member.

14. The wafer fixing apparatus of claim 1, wherein a UV-hardened layer is not used to couple the semiconductor wafer to the dicing stage.
